(19) United States
(12) Patent Application Publication
(10) Pub. No.: US 2012/0018783 A1
(43) Pub. Date: Jan. 26, 2012

(54) SEMICONDUCTOR DEVICE AND METHOD FOR MANUFACTURING SAME

(76) Inventors: Kazuaki Iwasawa, Kanagawa-ken (JP); Shigeo Kondo, Saitama-ken (JP); Hiroshi Akahori, Kanagawa-ken (JP); Kiyohito Nishihara, Kanagawa-ken (JP); Yingkang Zhang, Kanagawa-ken (JP); Masaki Kondo, Kanagawa-ken (JP); Hidenobu Nagashima, Mie-ken (JP); Takashi Ichikawa, Saitama-ken (JP)

(21) Appl. No.: 13/117,525

(22) Filed: May 27, 2011

(30) Foreign Application Priority Data
Jul. 20, 2010 (JP) 2010-163382

(51) Int. Cl. H01L 29/772; H01L 21/28

(52) U.S. Cl. 257/288; 438/592; 257/E21.19; 257/E29.242

(57) ABSTRACT

According to one embodiment, a method is disclosed for manufacturing a semiconductor device. A side face parallel to a channel direction of a plurality of gate electrodes provided above a semiconductor substrate is included as a part of an inner wall of an isolation groove provided between the adjacent gate electrodes. The method can include forming a first isolation groove penetrating through a conductive film serving as the gate electrode to reach the semiconductor substrate. The method can include forming a protection film covering a side wall of the first isolation groove including a side face of the gate electrode. The method can include forming a second isolation groove by etching the semiconductor substrate exposed to a bottom surface of the first isolation groove. The method can include oxidizing an inner surface of the second isolation groove provided on each of both sides of the gate electrode to form first insulating films, which are connected to each other under the gate electrode. In addition, the method can include filling an inside of the first isolation groove and an inside of the second isolation groove with a second insulating film.

### CROSS-REFERENCE TO RELATED APPLICATIONS

This application is based upon and claims the benefit of priority from the prior Japanese Patent Application No. 2010-163382, filed on Jul. 20, 2010; the entire contents of which are incorporated herein by reference.

### FIELD

Embodiments described herein relate generally to a semiconductor device and a method for manufacturing the same.

### BACKGROUND

In order to enhance the performance and achieve a reduction in the cost of a highly-integrated LSI, there is a need for a new progress in the microfabrication technique in the LSI manufacturing process. For example, in a NAND-type flash memory, a reduction in the size of a memory cell has progressed and a half pitch between memory strings is shifting to a generation of the half pitch equal to or less than 20 nm. Here, because a reduction in the on/off ratio of the channel current due to the so-called short channel effect becomes significant, a transistor in the memory cell region is likely to malfunction, resulting in degradation in the performance and reliability and also a reduction in the yield.

On the other hand, a method has been studied for suppressing the short channel effect with the use of an SOI (Silicon On Insulator) technique or SON (Silicon On Nothing) technique and thereby realizing the NAND-type flash memory of the generation of 20 nm half pitch.

However, for example, the conventional SOI technique requires complicated processes, such as the processes of epitaxially growing an SiGe layer as a sacrifice layer and then forming a groove (trench) communicating with the SiGe layer and subsequently removing the SiGe layer, which therefore poses a problem in productivity. Thus, there is a need for a highly productive approach capable of forming the SOI structure more conveniently.

### BRIEF DESCRIPTION OF THE DRAWINGS

FIG. 1 is a schematic view illustrating a plane configuration of a semiconductor device according to a first embodiment;

FIG. 2 is a schematic view illustrating a partial cross-section of the semiconductor device according to the first embodiment;

FIG. 3A to FIG. 6B are partial cross-sectional views schematically illustrating manufacturing processes of the semiconductor device according to the first embodiment;

FIGS. 7A and 7B are schematic cross-sectional views illustrating structural parameters of the semiconductor device according to the first embodiment;

FIGS. 8A and 8B are partial cross-sectional views schematically illustrating manufacturing processes of a semiconductor device according to a second embodiment;

FIG. 9 is a schematic view illustrating a partial cross-section of the semiconductor device according to the second embodiment; and

FIGS. 10A and 10B are schematic cross-sectional views illustrating structural parameters of the semiconductor device according to the second embodiment.

### DETAILED DESCRIPTION

In general, according to one embodiment, a method is disclosed for manufacturing a semiconductor device. A side face parallel to a channel direction of a plurality of gate electrodes provided above a semiconductor substrate is included as a part of an inner wall of an isolation groove provided between the adjacent gate electrodes. The method can include forming a first isolation groove penetrating through a conductive film serving as the gate electrode to reach the semiconductor substrate. The method can include forming a protection film covering a side wall of the first isolation groove including a side face of the gate electrode. The method can include forming a second isolation groove by etching the semiconductor substrate exposed to a bottom surface of the first isolation groove. The method can include oxidizing an inner surface of the second isolation groove provided on each of both sides of the gate electrode to form first insulating films, which are connected to each other under the gate electrode. In addition, the method can include filling an inside of the first isolation groove and an inside of the second isolation groove with a second insulating film.

Hereinafter, embodiments of the invention will be described with reference to the drawings. In the following embodiments, similar components in the drawings are marked with like reference numerals, and a detailed description is omitted as appropriate. Different components will be suitably described.

### First Embodiment

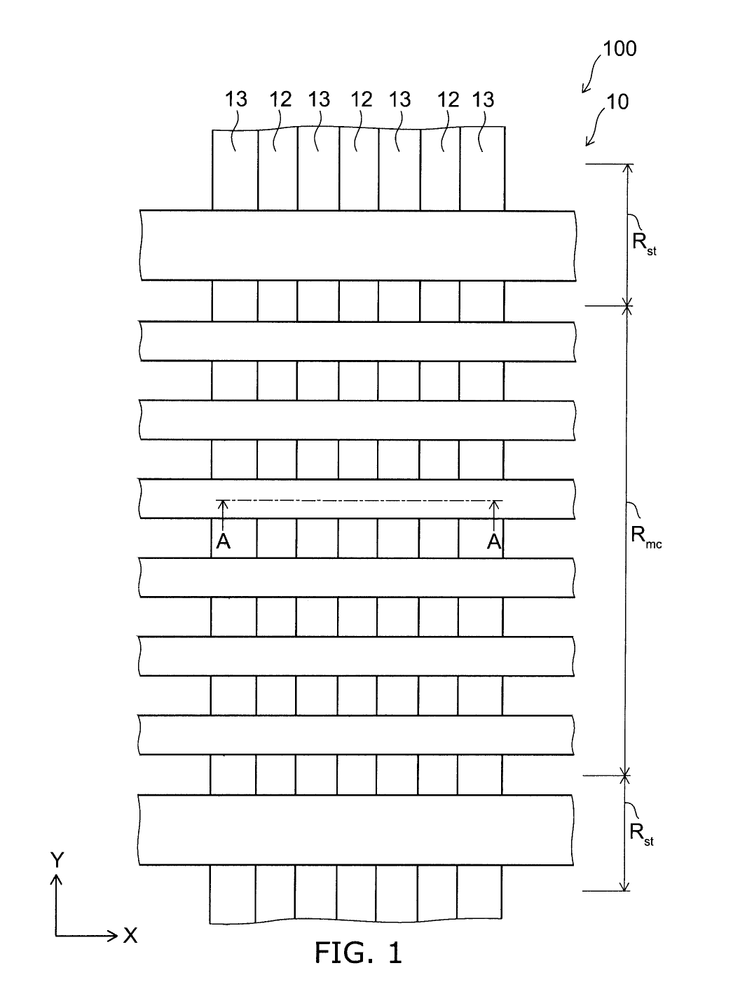

FIG. 1 is a plane configuration view schematically illustrating a semiconductor device 100 according to a first embodiment. The semiconductor device 100 is a NAND-type flash memory, for example, and FIG. 1 illustrates the configuration of a memory array section 10. The NAND-type flash memory includes the memory array section 10 for storing data and a peripheral circuit region (not illustrated) driving the memory array section 10.

As illustrated in FIG. 1, a memory cell region R_{mc} and a selection transistor region Rₛₜ are arranged in the memory array section 10, wherein the memory cell region R_{mc} is provided between two selection transistor regions Rₛₜ. In the Y direction in this view, a plurality of memory strings 13 and a plurality of STI's 12 are alternately arranged penetrating through both the memory cell region R_{mc} and the selection transistor region Rₛₜ. The STI 12 isolates the adjacent memory strings 13 from each other.

Furthermore, a plurality of control gate electrodes 27 and selection gate electrodes 29 are provided crossing the memory strings 13 and STI's 12 in the X direction. A memory cell is formed at a place where the memory string 13 intersects with the control gate electrode 27, and a selection transistor is formed at a place where the memory string 13 intersects with the selection gate electrode 29.

Corresponding to progress in the increasing capacity of the NAND-type flash memory, the structure of the memory array section 10 is miniaturized, and for example, the horizontal width of STI 12 is now approaching to 20 nm or less.

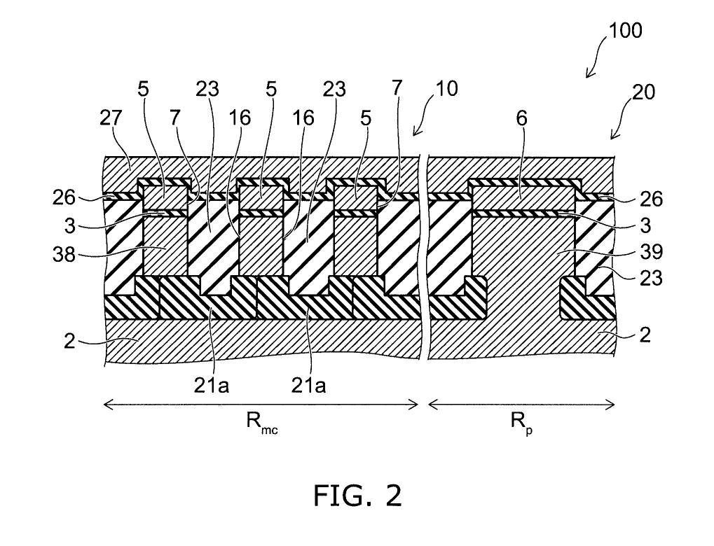

In the embodiment, a method for manufacturing the semiconductor device 100 will be described while illustrating a part of the memory cell region R_{mc} provided in the memory array section 10 and a part of a peripheral circuit region Rₚ. FIGS. 2 to 6B schematically illustrate an A-A cross-section of the memory cell region R_{mc} and a cross section of a transistor 20 provided in the peripheral circuit region Rₚ.

As illustrated in FIG. 2, the semiconductor device 100 includes a plurality of gate electrodes 5 provided via a gate insulating film 3 above a semiconductor substrate 2, wherein a side face 7 parallel to the direction of a channel of the gate electrode 5 serves as a part of an inner wall of an isolation groove 16, which is a first isolation groove, provided between the adjacent gate electrodes 5.

Here, the channel direction is the Y direction in which the memory string 13 formed in a stripe shape extends. The X direction orthogonal to the Y direction is the channel width direction.

In the direction perpendicular to the side face of the gate electrode 5 from each bottom portion of the isolation groove 16 provided on both sides of the gate electrode 5, SiO₂ films 21a which are two first insulating films extend. The two SiO₂ films 21a are connected to each other under the gate electrode 5 to provide an SOI structure in which an active region 38 under the gate electrode 5 is isolated from the semiconductor substrate 2.

The inside of the isolation groove 16 is filled with an SiO₂ film 23, which is a second insulating film, and furthermore, an insulating film 26 and the control gate electrode 27 are provided covering the upper portion of the gate electrode 5 and the isolation groove 16.

The channel width under a gate electrode 6 of the transistor 20 in the peripheral circuit region Rₚ is wider than that under the gate electrode 5. For this reason, under the gate electrode 6, SiO₂ films 21b are not connected to each other and the semiconductor substrate 2 is not isolated from an active region 39.

That is, in the semiconductor device 100 produced using the manufacturing method according to the embodiment, the SOI structure is provided only in the memory cell region R_{mc}.

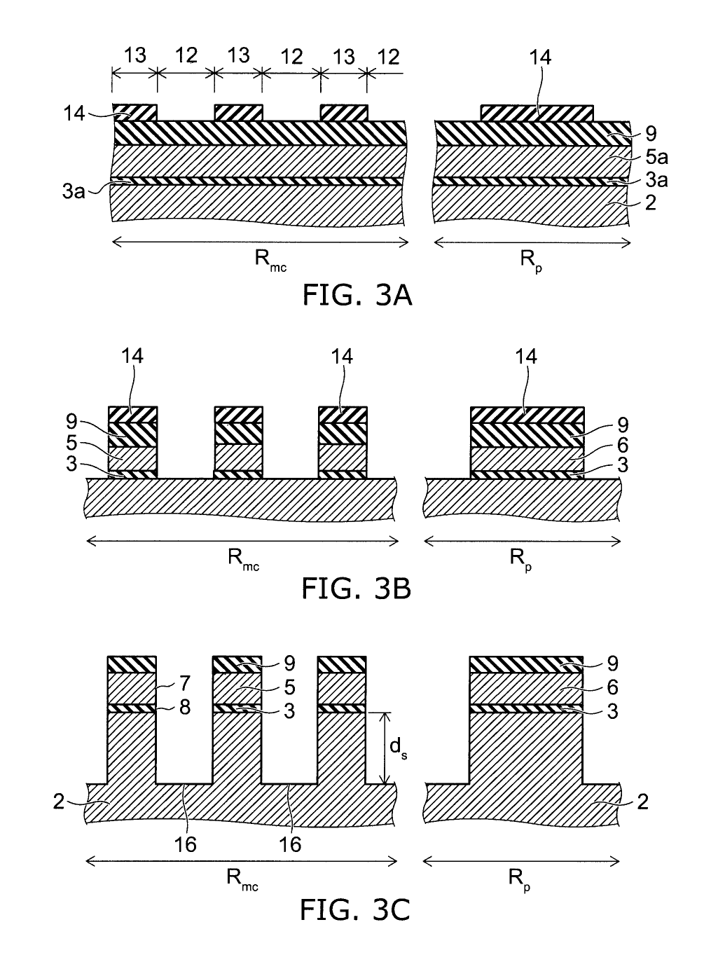

Hereinafter, the method for manufacturing the semiconductor device 100 is described with reference to FIGS. 3 to 6.

First, as illustrated in FIG. 3A, an SiON film with a thickness of 8 nm to serve as the gate insulating film 3 and a polysilicon film 5a with a thickness of 90 nm to serve as the gate electrode 5 are stacked above the semiconductor substrate 2. Furthermore, a silicon nitride film (SiN film) 9 with a thickness of 70 nm to serve as the mask of reactive ion etching (RIE) is formed.

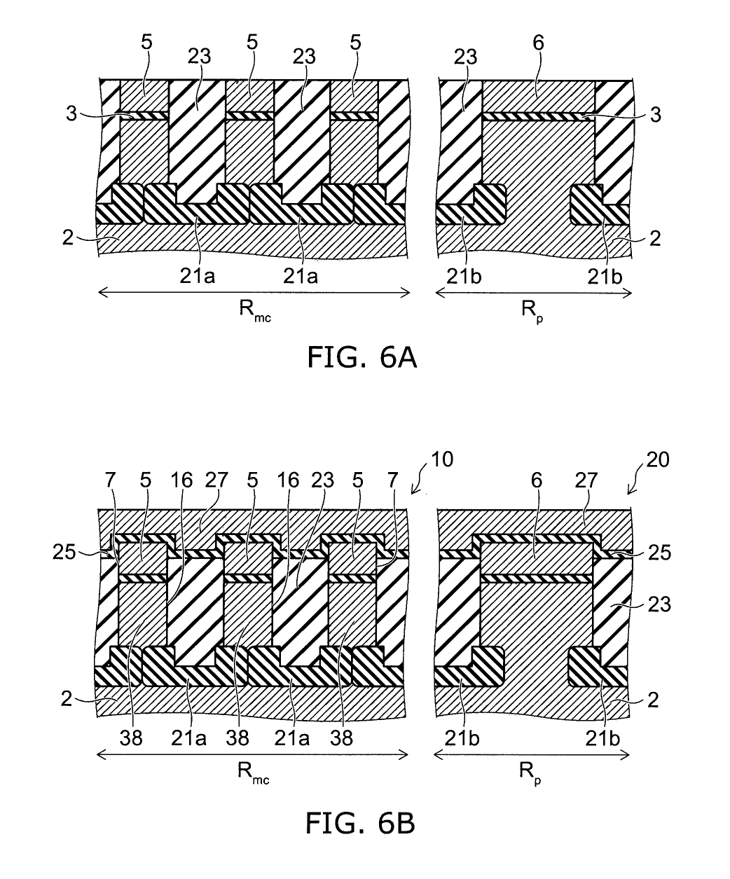

The SiN film 9 can be used also as a stopper of chemical mechanical polishing (CMP) (see FIG. 6A). As the semiconductor substrate 2, a silicon wafer can be used, for example.

Next, above the SiN film 9, a silicone oxide film (SiO₂ film) 14 to serve as the mask of RIE is formed and then is patterned using a photolithography technique. For example, the SiO₂ film 14 is formed in a stripe shape covering a region to serve as the memory string 13 illustrated in FIG. 1.

Subsequently, as illustrated in FIG. 3B, the SiN film 9, the polysilicon film 5a, and the SiON film 3a are sequentially etched, with the SiO₂ film 14 as the mask.

For the etching, RIE can be used, for example. A carbon tetrafluoride (CF₄) gas can be used in the etching of the SiN film 9, and a mixed gas of hydrogen bromide (HBr), oxygen (O₂), and CF₄ can be used in the etching of the polysilicon film 5a. Furthermore, a CHF₃ gas can be used in the etching of the SiON film 3a.

Then, in the memory cell region R_{mc}, a plurality of gate electrodes 5 is formed via the gate insulating film 3 above the semiconductor substrate 2. The gate electrodes 5 are formed in a stripe shape in the Y direction in which the memory string 13 extends, and are spaced apart from each other in the X direction with a space therebetween in which STI 12 is subsequently formed. On the other hand, in the peripheral circuit region Rₚ, the gate electrode 6 with the channel width wider than the gate electrode 5 is formed.

Furthermore, as illustrated in FIG. 3C, the semiconductor substrate 2 exposed between the gate electrodes 5 is etched to form the isolation groove 16 extending from the surface of the SiN film 9 to reach the semiconductor substrate 2.

Then, the etched depth d_{S} of the semiconductor substrate 2 can be set to a depth equal to or less than 50 nm (e.g., dₛ=20 nm) using high density plasma-chemical vapor deposition (HDP-CVD) or CVD using TEOS (TetraEthOxySilane) and O₃ gas (hereinafter referred to as TEOS/O₃) so that the inside of the isolation groove 16 can be filled.

Also in the peripheral circuit region Rₚ, the semiconductor substrate 2 is etched by the same depth dₛ.

The etching of the isolation groove 16 can be performed in the direction perpendicular to the surface of the semiconductor substrate 2 using an RIE condition with anisotropy. As the etching gas, a mixed gas of HBr, O₂, and CF₄ can be used, for example.

Furthermore, as illustrated in FIG. 3C, it is also possible to adjust the thickness of the SiO₂ film 12 in advance so that the whole etching mask (S1O₂ film 12) above the SiN film 9 may be removed when the etching of the isolation groove 16 is completed.

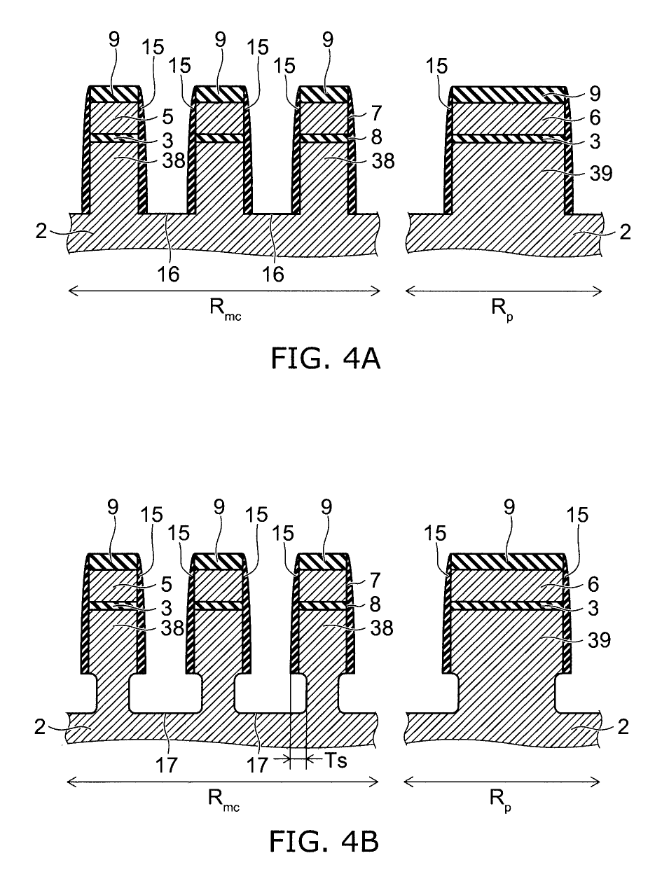

Next, as illustrated in FIG. 4A, a protection film 15 covering the inner wall of the isolation groove 16 is formed.

Specifically, in the surface of the semiconductor substrate 2 having the isolation groove 16 formed therein, a SiN film to serve as the protection film 15 is formed using ALD (atomic layer deposition), for example. Subsequently, this SiN film formed in the bottom portion of the isolation groove 16 and above the SiN film 9 is selectively etched using the anisotropy condition of RIE. Thus, as illustrated in FIG. 4A, the protection film 15 can be left in the inner wall of the isolation groove 16.

The protection film 15 is formed also in the side face of the gate electrode 6 and gate insulating film 3 provided in the peripheral circuit region Rₚ.

Next, as illustrated in FIG. 4B, with the protection film 15 and SiN film 9 as the mask, the semiconductor substrate 2 exposed to the bottom surface of the isolation groove 16 is etched to form an isolation groove 17 which is a second isolation groove. For example, with the use of an RIE condition with suppressed anisotropy, a condition allowing the etching to proceed also in the horizontal direction parallel to the surface of the semiconductor substrate 2 is used. As the etching gas, a sulfur hexafluoride (SF₆) gas can be used, for example.

As a result, as illustrated in FIG. 4B, the isolation groove 17 extends by T_{S} in the direction perpendicular to the side face 7 of the gate electrode 5, and under the gate electrode 5 the width of the lower part of the active region 38 narrows.

Also in the peripheral circuit region Rₚ, under the gate electrode 6 the lower part of the active region 39 is etched.

Subsequently, the surface of the semiconductor substrate 2 exposed to the inner wall of the isolation groove 17 is thermally oxidized to form the SiO₂ film 21a which is the first insulating film.

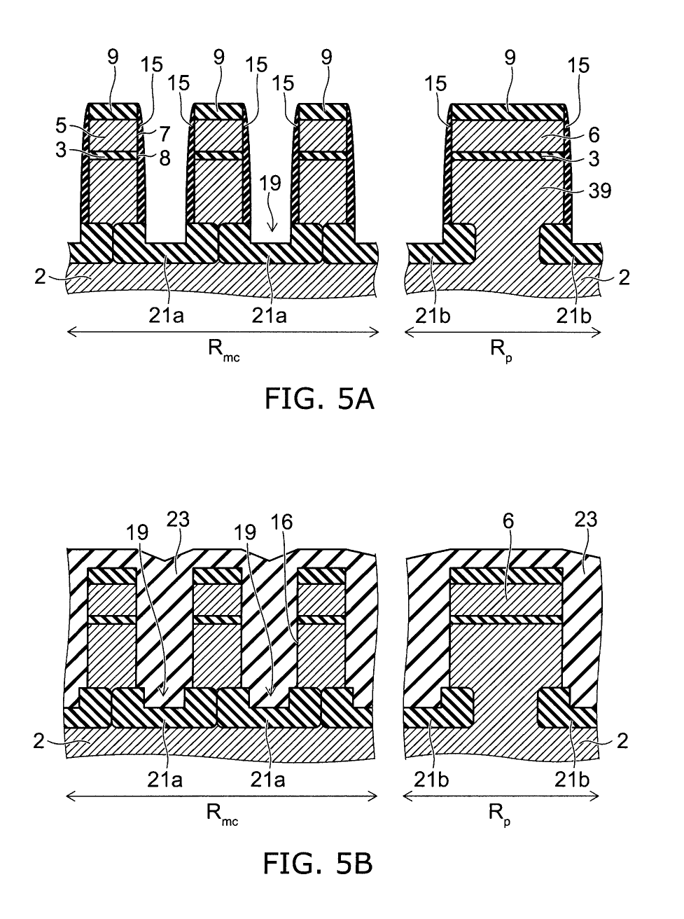

As illustrated in FIG. 5A, in the semiconductor device 100 according to the embodiment, two SiO₂ films 21a, which are formed by oxidizing the inner surface of the isolation groove 17 provided on both sides of the gate electrode 5, are connected to each other under the gate electrode 5.

The SiO₂ film 21a formed by thermal oxidation expands more than the oxidized region of the semiconductor substrate 2, and is formed extending into the isolation groove 17. Then, once the inside of the isolation groove 17 is filled with the SiO₂ film 21a, O₂ is no longer supplied and therefore the oxidization of the semiconductor substrate 2 stops. At this time, if the SiO₂ films 21a are not connected to each other under the gate electrode 5, the SOI structure illustrated in FIG. 5A cannot be formed.

Then, in the method of manufacturing the semiconductor device according to the embodiment, as described later, the SOI structure can be reliably formed by appropriately adjusting the extension width T_{S} of the isolation groove 17 and thereby connecting the SiO₂ films 21a to each other under the gate electrode 5.

On the other hand, in the peripheral circuit region Rₚ, because the width of the active region 39 (gate electrode 6) is set wide, the SiO₂ films 21b formed from the both sides of the active region 39 is not be connected to each other under the gate electrode 6 and thus the SOI structure can be formed only in the memory cell region R_{mc}.

Moreover, because the inner wall of the isolation groove 16 is covered with the protection film 15, the degradation of the gate electrodes 5, 6 and the gate insulating film 3 can be prevented during thermal oxidation.

Next, as illustrated in FIG. 5B, for example, after the protection film 15 is etched using rare fluoric acid, phosphoric acid heated to approximately 150° C., or the like, the SiO₂ film 23 which is the second insulating film is formed above the SiO₂ film 21a, so that the inside of the isolation groove 16 can be filled with the SiO₂ film 23.

When there is a space 19, which is not filled with the SiO₂ film 21a, in the inside of the isolation groove 17, the space 19 is filled simultaneously with the SiO₂ film 23.

If the isolation groove 16 is deep when the spacing between the gate electrodes 5 has been reduced due to high integration of the semiconductor device 100, it is difficult to fill the inside of the isolation groove 16 with the insulating film.

In the embodiment, by limiting the etched depth dₛ of the semiconductor substrate 2 to 50 nm or less, for example, the isolation groove 16 is formed shallow. For this reason, even if the spacing between the gate electrodes 5 narrows, the inside of the isolation groove 16 can be filled with the SiO₂ film 23 using a method, such as HDP-CVD, TEOS/O₃, a coating method, LP-CVD, or ALD, for example.

Furthermore, although the above-described embodiment shows an example in which the protection film 15 is removed, it is also possible to leave the protection film 15. Then, in the side face of the gate electrode 5, the protection film 15 may isolate the control gate electrode 27 (see FIG. 6B) from the gate electrode 5.

Next, as illustrated in FIG. 6A, the surface of the SiO₂ film 23 is planarized using CMP. In this case, the SiN film 9 provided above the gate electrode 5 can serve as a stopper to prevent polishing of the gate electrode 5.

Subsequently, as illustrated in FIG. 6B, the surface of the SiO₂ film 23 filling the isolation groove 16 is etched back and the control gate electrode 27 is formed via an insulating film 25 (a third insulating film).

The SiO₂ films 21a extending from the respective bottom portions of the isolation groove 16 to the direction perpendicular to the side face 7 of the gate electrode 5 are connected to each other under the gate electrode 5 to form the

SOI structure in which the active region 38 is isolated from the semiconductor substrate 2. Furthermore, above the SiO₂ film 21a, there is provided the second insulating film SiO₂ film 23 filling the inside of the isolation groove 16 and having the density lower than the SiO₂ film 21a.

For example, the density of the SiO₂ film 23 formed using HDP-CVD or TEOS/O₃ becomes lower than the density of the SiO₂ film 21a formed by thermal oxidation.

Also in the peripheral circuit region Rₚ, the manufacturing process similarly progresses, and the transistor 20 with a wide channel width is formed.

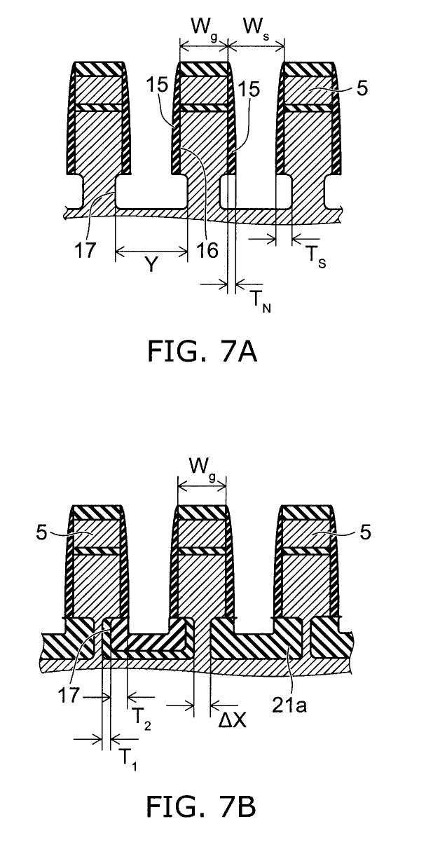

Next, referring to FIGS. 7A and 7B, conditions for connecting the adjacent SiO₂ films 21a to each other are described.

FIGS. 7A and 7B are schematic cross-sectional views illustrating structural parameters of the semiconductor device 100 according to the embodiment. FIG. 7A illustrates a cross-section in a state where the isolation grooves 16 and 17 are formed in the semiconductor substrate 2, and FIG. 7B illustrates a cross-section after thermally oxidizing the inner surface of the isolation groove 17.

As illustrated in FIG. 7A, the width in the X direction of the isolation groove 17 is denoted by Y, the width of the gate electrode 5 is denoted by W_{g}, and the spacing between the adjacent gate electrodes 5 is denoted by W_{S}. The width of the protection film 15 formed in the inner wall of the isolation groove 16 is denoted by T_{N}.

On the other hand, FIG. 7B illustrates a state where the adjacent SiO₂ films 21a are not connected to each other but are spaced apart from each other by a distance ΔX. The thickness of the SiO₂ film 21a thermally oxidized in the inner surface of the isolation groove 17 is denoted by Tₒₓ, the width of the thermally oxidized semiconductor substrate 2 is denoted by T₁, and the width of the SiO₂ film 21a expanding into an isolation groove 37 is denoted by T₂.

The spacing ΔX between the adjacent SiO₂ films 21a is expressed by the following equation.

ΔX=W_{g}+2T_{N}−2T_{S}−2T₁

The width Y of the isolation groove 17 is expressed by the following equation.

Y=W_{S}−2T_{N}+2T_{S}

The ratio of the width T₁ of the thermally oxidized semiconductor substrate 2 and the width T₂ of the SiO₂ film 21a expanding into the isolation groove 37 is expressed by the following equation.

T₁:T₂=0.44:0.56

Therefore, the thickness Tₒₓ of the SiO₂ film 21a is expressed by the following equation.

Tₒₓ=2.27T₁

For example, when W_{g}=W_{S}=15 nm, T_{N}=3 nm, and T_{S}=5 nm, then the spacing ΔX between the adjacent SiO₂ films 21a and the thickness Tₒₓ are expressed by the following equations, respectively.

ΔX=W_{g}+2T_{N}−2T_{S}−2T₁=0

T_{OX}=2.27T₁ to 12.4 nm

Therefore, for example, if thermal oxidization is performed under the condition to form the SiO₂ film with a thickness equal to or greater than 13 nm, the adjacent SiO₂ films 21a can be connected to each other to form the SOI structure under the gate electrode 5.

On the other hand, once the inside of the isolation groove 37 is filled with the thermally oxidized SiO₂ film 21a, the progress of the oxidization of the semiconductor substrate 2 stops and ΔX does not narrow any more.

Then, T₂ and T₁ are expressed by the following equations, respectively.

T₂=0.5Y

T₁=0.5×(0.44/0.56)Y

Therefore, the minimum width ΔXₘᵢₙ of ΔX is expressed by the following equation.

ΔXₘᵢₙ=W_{g}−0.79W_{S}+3.58T_{N}−3.58T_{S}

Even if the oxidation time of the inner surface of the isolation groove 37 is increased, the spacing between the adjacent SiO₂ films 21a does not narrow beyond ΔXₘᵢₙ. Therefore, in order to form the SOI structure by connecting the S1O₂ films 21a to each other under the gate electrode 5, a condition ΔXₘᵢₙ<0 is required.

That is, the extension width T_{S} satisfying the following equation can be set.

W_{g}<0.79W_{S}−3.58T_{N}+3.58T_{S}

As described above, in the method of manufacturing the semiconductor device 100 according to the embodiment, the SOI structure can be formed under the gate electrode 5 by providing the protection film 15 in the inner wall of the isolation groove 16, forming the isolation groove 17 under the isolation groove 16, and furthermore thermally oxidizing the inner surface thereof.

Then, this SOI structure can be selectively formed only in regions where the channel width is narrow, by changing the channel width of the gate electrode.

Thus, according to the embodiment, there is no need to form the SOI structure in advance in the semiconductor substrate, and for example, the simple addition of a process of forming the protection film 15 in the inner wall of the isolation groove 16 and a process of thermally oxidizing the inner surface of the isolation groove 17 to the manufacturing process of the NAND-type flash memory makes it possible to conveniently manufacture a semiconductor device with the SOI structure and achieve an increase in productivity.

### Second Embodiment

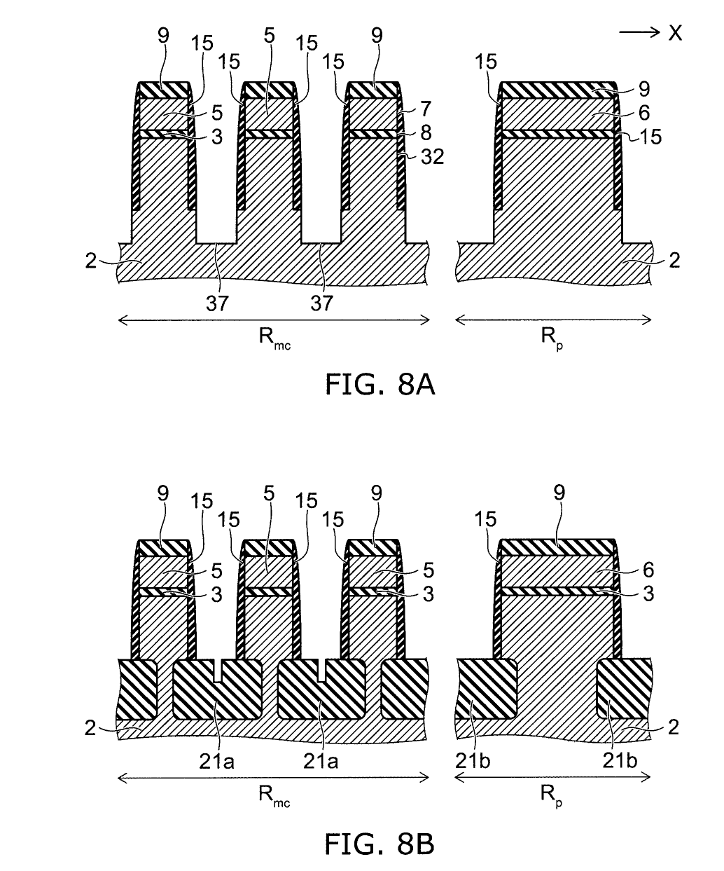

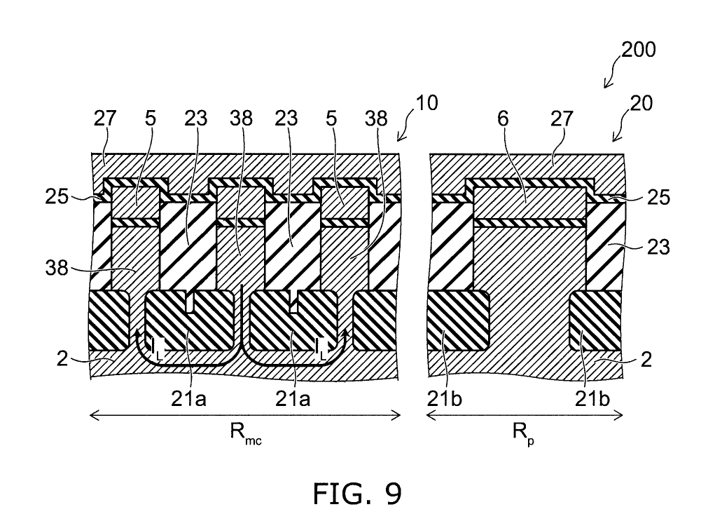

FIGS. 8A and 8B and FIG. 9 are partial cross-sectional views schematically illustrating manufacturing processes of a semiconductor device 200 according to a second embodiment. These views illustrate the A-A cross section in the plane configuration illustrated in FIG. 1.

The method for manufacturing the semiconductor device according to the embodiment, as illustrated in FIG. 8A, differs from the first embodiment illustrated in FIG. 4B in that the isolation groove 37 formed under the isolation groove 16 is not extended in the X direction perpendicular to the side face of the gate electrode 5.

Furthermore, as illustrated in FIG. 8B, the SiO₂ film 21a, which is formed by thermally oxidizing the inner surface of the isolation groove 37, may be spaced apart from each other.

In the embodiment, for example, utilizing the anisotropy condition of RIE, etching is performed in the direction (see FIG. 4A) perpendicular to the surface of the semiconductor substrate 2 exposed to the bottom surface of the isolation groove 16 to form the isolation groove 37. As the etching gas, a mixed gas of HBr, O₂, and CF₄ can be used, for example.

FIG. 9 schematically illustrates a partial cross-section of the semiconductor device 200.

In the semiconductor device 200 according to the embodiment, for example, because the SiO₂ films 21a are spaced apart from each other, there is a leak path I_{L} via the semiconductor substrate 2 between the active regions 38 which are isolated from each other by the STI structure in which the isolation groove 16 is filled with the SiO₂ film 23.

However, for example, if the SiO₂ films 21a formed on both sides of the gate electrode 5 are provided close to each other and the spacing between the adjacent SiO₂ films 21a is sufficiently narrow, the resistance of the leak path I_{L} can be increased to reduce the leakage current. Furthermore, if a part of the semiconductor substrate sandwiched by the adjacent SiO₂ films 21a is depleted, the active region 38 can be electrically isolated from the semiconductor substrates 2, and thus the same effect as that of the SOI can be also obtained.

That is, the SiO₂ films 21a formed on both sides of the gate electrode 5 may be provided close to each other in a range in which the leakage current can be suppressed to a desired level or less, even though these SiO₂ films 21a are not connected to each other under the gate electrode 5.

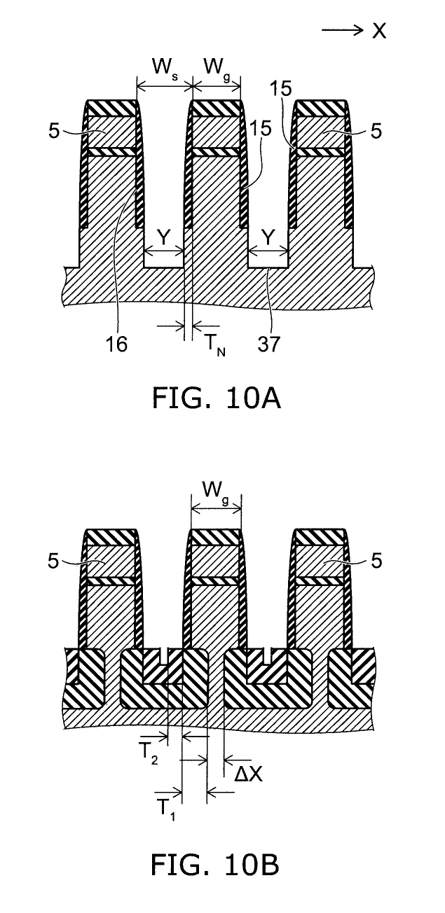

FIGS. 10A and 10B are schematic cross-sectional views showing the structural parameters of the semiconductor device 200 according to the embodiment. FIG. 10A illustrates a cross-section in a state where the isolation groove 37 is formed in the semiconductor substrate 2, and FIG. 10B illustrates a cross section after thermally oxidizing the inner surface of the isolation groove 37.

As with FIGS. 7A and 7B described above, the width in the X direction of the isolation groove 37 is denoted by Y, the width of the gate electrode 5 is denoted by W_{g}, and the spacing between the adjacent gate electrodes 5 is denoted by W_{S}. The width of the protection film 15 formed in the inner wall of the isolation groove 16 is denoted by T_{N}.

In the embodiment, the spacing ΔX between the SiO₂ films 21a is expressed by the following equation.

Δₓ=W_{g}+2T_{N}−2T₁

Moreover, the width Y of the isolation groove 37 is expressed by the following equation.

Y=W_{S}−2T_{N}

Once the inside of the isolation groove 37 is filled with the thermally oxidized SiO₂ film 21a, the progress of the oxidization of the semiconductor substrate 2 stops and ΔX does not narrow any more. Then, T₂ and T₁ are expressed by the following equations, respectively.

T₂=0.5Y

T₁=0.5×(0.44/0.56)Y

Therefore, the minimum width ΔXₘᵢₙ of ΔX is expressed by the following equation.

ΔXₘᵢₙ=W_{g}−0.79W_{S}+3.58T_{N}

The width W_{g} of the gate electrode 5, the spacing W_{S} between the gate electrodes 5, and the width T_{N} of the protection film 15 can be applicable with a relatively high accuracy and ΔXₘᵢₙ can be controlled with a high accuracy.

On the other hand, even if the oxidation time of the inner surface of the isolation groove 37 is increased, the spacing between the adjacent SiO₂ films 21a does not narrow beyond ΔXₘᵢₙ. Therefore, in order to form the SOI structure by connecting the SiO₂ films 21a to each other under the gate electrode 5, a condition ΔXₘᵢₙ<0 is required.

That is, the following equation may be satisfied.

W_{g}<0.79W_{S}−3.58T_{N}

According to the above equation, even if T_{N}=0, W_{g}<0.79W_{S}. That is, as illustrated in the embodiment, when the width of the isolation groove 37 is not extended by etching, the width W_{g} of the gate electrode 5 is set to be narrower than the spacing Wₛ between the adjacent gate electrodes 5. This makes it possible to connect the adjacent SiO₂ film 21a to each other and thereby form the SOI structure.

On the other hand, if the width of the isolation groove 17 is extended in the direction perpendicular to the side face of the gate electrode 5 as illustrated in the first embodiment, the SiO₂ films 21a adjacent to each other under the gate electrode 5 can be connected to each other even if W_{S} is equal to W_{g}, for example.

Furthermore, also in the semiconductor device 100 according to the first embodiment, under the gate electrode 5 the two SiO₂ films 21a may be spaced apart from each other.

In the above, the invention has been described with reference to the first and second embodiments according to the invention, however, the invention is not limited to these embodiments. For example, the design changes, modification of materials, and the like which those skilled in the art may make according to the state of the art at the time of this application, and embodiments based on the same technical idea as that of the invention are also included in the technical scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, a side face parallel to a channel direction of a plurality of gate electrodes provided above a semiconductor substrate being included as a part of an inner wall of an isolation groove provided between the adjacent gate electrodes, the method comprising:
forming a first isolation groove penetrating through a conductive film serving as the gate electrode to reach the semiconductor substrate;
forming a protection film covering a side wall of the first isolation groove including a side face of the gate electrode;
forming a second isolation groove by etching the semiconductor substrate exposed to a bottom surface of the first isolation groove;
oxidizing an inner surface of the second isolation groove provided on each of both sides of the gate electrode to form first insulating films, the first insulating films being connected to each other under the gate electrode; and
filling an inside of the first isolation groove and an inside of the second isolation groove with a second insulating film.

2. The method according to claim 1, wherein
the semiconductor substrate includes a memory cell region and a peripheral circuit region, the peripheral circuit region having a gate electrode having a channel width wider than a gate electrode of the memory cell region, and
the first insulating films are connected to each other under the gate electrode arranged in the memory cell region.

3. The method according to claim 1, wherein an SOI (Silicon On Insulator) structure is formed under the gate electrode arranged in the memory cell region, and an SOI structure is not formed under the gate electrode of the peripheral circuit region.

4. The method according to claim 3, wherein the gate electrode is formed in a stripe shape in the memory cell region.

5. The method according to claim 1, wherein
the semiconductor substrate is a silicon wafer, and
the first insulating film is an SiO₂ film formed by thermally oxidizing.

6. The method according to claim 1, wherein the conductive film is a polysilicon film.

7. The method according to claim 1, wherein a depth of the first isolation groove from a surface of the semiconductor substrate is within 50 nm.

8. The method according to claim 1, wherein the protection film is a silicon nitride film formed by using ALD.

9. The method according to claim 1, wherein the second insulating film is an SiO₂ film formed by using HDP-CVD or CVD using TEOS and O₃ gas.

10. The method according to claim 1, wherein the second isolation groove is etched under less anisotropy condition than in etching of the first isolation groove.

11. The method according to claim 1, wherein a width of the second isolation groove in a direction perpendicular to a side face of the gate electrode is formed wider than a width of the first isolation groove.

12. The method according to claim 11, wherein
W_{g}<0.79W_{S}−3.58T_{N}+3.58T_{S}
is satisfied when an adjacent spacing of the plurality of gate electrodes is denoted by W_{S}, a width of the gate electrode in a channel width direction perpendicular to the side face of the gate electrode is denoted by W_{g}, a thickness of the protection film is denoted by T_{N}, and an extension width of the second isolation groove is denoted by T_{S}.

13. The method according to claim 1, wherein a width of the gate electrode in the channel width direction is narrower than an adjacent spacing of the plurality of gate electrodes.

14. The method according to claim 1, further comprising:
forming a third insulating film covering the second insulating film and the gate electrode; and
forming a control gate electrode on the third insulating film.

15. The method according to claim 14, wherein the third insulating film includes the protection film.

16. A semiconductor device comprising:
a semiconductor substrate;
a gate electrode provided above the semiconductor substrate;
two first insulating films provided on both sides of the gate electrode, extending in a direction perpendicular to a side face of the gate electrode from each bottom portion of isolation grooves, and connected to each other under the gate electrode, the isolation groove penetrating through a conductive layer serving as the gate electrode to reach the semiconductor substrate; and
a second insulating film having a density lower than a density of the first insulating film and filling an inside of the isolation groove.

17. The device according to claim 16, wherein
the semiconductor substrate is a silicon wafer, and
the first insulating film is an SiO₂ film formed by thermally oxidizing.

18. The device according to claim 16, wherein the second insulating film is an SiO₂ film formed using HDP-CVD or CVD using TEOS and O₃ gas.

19. A semiconductor device comprising:
a semiconductor substrate;
a gate electrode provided above the semiconductor substrate;
first insulating films provided on both sides of the gate electrode and extending in a direction perpendicular to a side face of the gate electrode from each bottom portion of isolation grooves, the isolation groove penetrating through a conductive layer serving as the gate electrode to reach the semiconductor substrate; and
a second insulating film having a density lower than a density of the first insulating film and filling an inside of the isolation groove,
the first insulating films being closely situated to each other via a part of the semiconductor substrate under the gate electrode.
